(19) United States
(12) Patent Application Publication
(10) Pub. No.: US 2005/0220241 A1
(43) Pub. Date: Oct. 6, 2005

(54) Mean power frequency discriminator, frequency phase locked loop circuit and digital television demodulator using the same

(76) Inventors: Junling Zhang, Yongin-si (KR); Ki-Dong Kang, Anyang-si (KR)

Correspondence Address: HARNESS, DICKEY & PIERCE, P.L.C., P.O. BOX 8910, RESTON, VA, 20195, US

(21) Appl. No.: 11/053,924

(22) Filed: Feb. 10, 2005

(30) Foreign Application Priority Data
Apr. 3, 2004 (KR) 2004-23176

(51) Int. Cl. H03F 1/14

(52) U.S. Cl. 375/376; 327/156

(57) ABSTRACT

Exemplary embodiments of the present invention provide a frequency phase locked loop circuit, which may enable a frequency and/or phase of a sampled signal to be tracked within a short time. Exemplary embodiments of the present invention also provide a digital television demodulator, which may use the frequency phase locked loop circuit. Exemplary embodiments of the frequency phase locked loop circuit may include a mean power frequency discriminator, a mean calculator, a phase discriminator, a loop-filter, and an adder. The frequency phase locked loop circuit may obtain a carrier frequency through a path and may track a phase of the carrier frequency through another path.

This application claims the priority of Korean Patent Application No. 2004-23176, filed on Apr. 3, 2004, in the Korean Intellectual Property Office, the disclosure of which is incorporated herein in its entirety by reference.

### BACKGROUND OF THE INVENTION

1. Field of the Invention

Exemplary embodiments of the present invention relate to digital televisions. More particularly, exemplary embodiments of the present invention relate to a mean power frequency discriminator, which may output an error signal including information regarding an offset carrier frequency and/or a phase of a carrier signal. The offset carrier frequency may be applied to, for example, a digital television (DTV) demodulator (for example, an Advanced Television Systems Committee Digital Television (ATSC-DTV) demodulator).

2. Description of the Related Art

A related art DTV (for example, an ATSC DTV) demodulator, which may be used in a DTV (for example, an ATSC DTV) receiver may demodulate an analog signal, which may have been transmitted from a DTV (for example, an ATSC DTV) transmitter. The DTV (for example, an ATSC DTV) receiver may acquire a carrier frequency of the analog signal. The DTV (for example, an ATSC DTV) receiver may utilize a frequency phase locked loop circuit and may acquire the carrier frequency.

To demodulate the analog signal, the DTV (for example, an ATSC DTV) demodulator may track and acquire the carrier frequency and may track a phase of the carrier frequency.

FIG. 1 is a block diagram of a related art DTV (for example, an ATSC DTV) demodulator. Referring to FIG. 1, a DTV (for example, an ATSC DTV) demodulator 100 may include an analog-to-digital (ADC) 110, a poly phase filter (PPF) 120, a multiplier 130, a filter 140, an up converter 150, a symbol timing recoverer (STR) 160, a frequency and phase locked loop circuit (FPLL) 170, a number controlled oscillator (NCO) 180, and a phase shifter 190.

The ADC 110 may convert an analog signal R(t), which may be transmitted from a DTV (for example, an ATSC DTV) transmitter, (not shown) into a digital signal.

The PPF 120 may receive the digital signal from the ADC 110 and may generate a signal R[tₙ]. The signal R[tₙ] may be sampled at a sampling frequency

$${f}_{S} ( = \frac{1}{{T}_{S}} ) ,$$

where T_{S} may denote a sampling time, tₙ=n×T_{S}, and n may be an integer. The operation of the PPF 120 may be controlled by a control signal C1, which may be output from the STR 160.

The multiplier 130 may further include two multipliers 131 and 132.

The multiplier 131 may multiply the sampled signal R[tₙ] by a frequency sinusoidal signal fs1 and may output a branch signal, which may be in-phase signal with the sampled signal R[tₙ]. The multiplier 132 may multiply the sampled signal R[tₙ] by another frequency sinusoidal signal fs2 and may output another branch quadrature signal Q′[tₙ] with the sampled signal R[tₙ].

The filter 140 may include two matched filters (MFs) 141 and 142. The MF 141 may pass a lower frequency signal, which may be contained in the first branch signal I′[tₙ] and may output another branch signal I[tₙ]. The MF 142 may pass a lower frequency signal, which may be contained in the branch signal Q′[tₙ], and may output another branch signal Q[tₙ].

The up converter 150 may transmit a real number component signal Re[tₙ], which may be extracted from the sampled signal R[tₙ], using branch signals I[tₙ] and Q[tₙ], to the STR 160 and the PFLL 170. The up converter 150 may transmit an imaginary number component signal Im[tₙ], which may be extracted from the sampled signal R[tₙ], using branch signals I[tₙ] and Q[tₙ], to the PFLL 170.

The STR 160 may output a control signal C1, which may control the sampling frequency

$${f}_{S} ( = \frac{1}{{T}_{S}} )$$

and a timing phase in the PPF 120, which may use the real number component signal Re[tₙ].

The FPLL 170 may use the real and imaginary number component signals Re[tₙ] and Im[tₙ] any may output an error signal e[tₙ]. The error signal e[tₙ] may include information concerning frequency and phase offset of the sampled signal R[tₙ].

NCO 180 may output the frequency sinusoidal signal fs1, cos((ω_{C}+Δω)tₙ+φ)). The frequency sinusoidal signal fs1 may be determined by the error signal e[tₙ], which may be output from the FPLL 170.

The phase shifter 190 may shift a phase of the frequency sinusoidal signal fs1 by 90° and may output the frequency sinusoidal signal fs2, sin((ω_{C}+Δω)tₙ+φ)). Δω and φ may denote frequency offset and phase offset of the sampled signal R[tₙ], respectively, between the DTV (for example, an ATSC DTV) transmitter and the DTV (for example, an ATSC DTV) demodulator 100.

The analog signal R(t), which may include a pilot tone, may be transmitted from the DTV (for example, an ATSC DTV) transmitter. and a frequency and phase of a carrier signal may be more reliably tracked using the FPLL 170.

The analog signal R(t) may not include the pilot tone or the pilot tone become faint (for example, during a transmission process) and tracking of the frequency and phase of the carrier signal, which may use the FPLL 170, may be more unreliable.

When a DTV (for example, an ATSC DTV) receiver receives the analog signal R(t), for example, through multipath channels, the pilot tone of the analog signal R(t) may fade (for example, substantially fade). The fading of the pilot tone of the analog signal R(t), may cause the tracking of the frequency and/or phase of the carrier signal, which may be through the use of the FPLL 170, more unreliable.

### SUMMARY OF THE INVENTION

Exemplary embodiments of the present invention provide a mean power frequency discriminator, a frequency phase locked loop circuit, and a digital television demodulator (for example, an ATSC DTV demodulator), which may enable a frequency and phase of a carrier signal to be tracked within a shorter time.

According to an exemplary embodiment of the present invention, a frequency phase locked loop circuit may include a mean power frequency discriminator, a mean calculator, a phase discriminator, a loop-filter, and an adder. The frequency phase locked loop circuit may receive a first signal (for example, a branch in-phase signal) with a sampled signal, a second signal (for example, a branch quadrature signal) with the sampled signal, and real and imaginary number component signals of the sampled signal. The frequency phase locked loop circuit may use the received signals to determine a carrier frequency and/or phase of the sampled signal. The mean power frequency discriminator may perform an operation on the first and/or second signals to output a first error signal, which may correspond to a frequency offset of the sampled signal. The mean calculator may calculate a mean of the first error signal to output a second error signal, which may comprise information concerning frequency offset of a carrier signal. The phase discriminator may utilize the real and imaginary number component signals to output a signal, which may include information concerning phase offset of the carrier signal. The loop-filter may reduce high frequency noise from the signal, which may be output from the phase discriminator. The first adder may add the second error signal to a signal output from the loop-filter, and may output a third error signal, which may include information concerning the carrier frequency and/or phase offset of the sampled signal. The frequency phase locked loop circuit may obtain the carrier frequency through the mean power frequency discriminator, the mean calculator, and the first adder and may track a phase of the carrier frequency through the phase discriminator, the loop-filter, and the first adder.

According to another exemplary embodiment of the present invention, digital television demodulator (for example, an Advanced Television Systems Committee Digital Television (ATSC-DTV) demodulator) may include an analog-to-digital converter, a poly phase filter, a multiplier, a low-pass filter, an up converter, a symbol timing recoverer, a frequency phase locked loop circuit, a number controlled oscillator, and a phase shifter. The analog-to-digital converter may convert an analog signal transmitted from a digital television transmitter (for example, an Advanced Television Systems Committee Digital Television (ATSC-DTV) transmitter) into a digital signal. The poly phase filter may receive the digital signal from the analog-to-digital converter and a control signal from a symbol timing recoverer and may generate a sampled signal that is sampled at a sampling frequency f_{S}, which may vary according to the control signal. The multiplier may receive the sampled signal and first and second frequency sinusoidal signals and may output a first signal (for example, a branch in-phase signal) with the sampled signal and a second signal (for example, a branch quadrature signal) with the sampled signal. The low-pass filter may pass lower frequency signals of the first and second signals and may output third and fourth signals (for example, branch signals), respectively. The up converter may output real and imaginary number component signals, which may be extracted from the sampled signal, using the third and/or fourth branch signals. The symbol timing recoverer may output the control signal using the real number component signal. The frequency phase locked loop circuit may output a third signal, which may comprise information concerning frequency offset and/or phase offset of the sampled signal, using the first and second signals and the real and imaginary number component signals. The number controlled oscillator may output the first frequency sinusoidal signal, an oscillation frequency of which may be determined by the third signal output from the frequency phase locked loop circuit. The phase shifter may shift a phase of the first frequency sinusoidal signal by an angle and may output the second frequency sinusoidal signal.

According to another exemplary embodiment of the present invention, a frequency phase locked loop circuit may receive at least a first signal (for example a branch signal) in phase with a sampled signal, a second signal (for example, a branch signal) out of phase with the sampled signal, and real and imaginary number component signals of the sampled signal. The frequency phase locked loop circuit may output an error signal, which may include information concerning a carrier frequency and/or phase offset of the sampled signal.

In another exemplary embodiment of the present invention, a method for obtaining a carrier frequency and tracking a phase of the carrier frequency is provided. The method may comprise performing an operation on a first and a second signal to output a first error signal corresponding to a frequency offset of a sampled signal. A mean of the first error signal and output a second error signal may be calculated and may include information concerning frequency offset of a carrier signal. A first output signal may be output and may include information concerning phase offset of the carrier signal based on a real and imaginary number component signals. A second output signal may be produced by reducing noise in the first output signal and a third output signal may be produced based on the second error signal and the second output signal. The third output signal may include information concerning the carrier frequency and phase offset of the sampled signal. The carrier frequency may be obtained and the phase of the carrier frequency may be tracked based on the information in the third output signal.

In another exemplary embodiment of the present invention, a method for producing an error signal including information concerning the frequency carrier offset of a carrier signal is provided. The method may comprise filtering at least a first signal and a second signal (for example, branch signals) according to a Nyquist criterion to output a third signal and a fourth signal (for example, branch signals), performing square operations on the third signal and the fourth signal, and adding the third signal and the fourth signal to output an error signal, which may include information concerning the frequency carrier offset of a carrier signal.

### BRIEF DESCRIPTION OF THE DRAWINGS

Exemplary embodiments of the present invention will become more apparent with reference to the attached drawings in which:

FIG. 1 is a block diagram of a related art ATSC DTV demodulator;

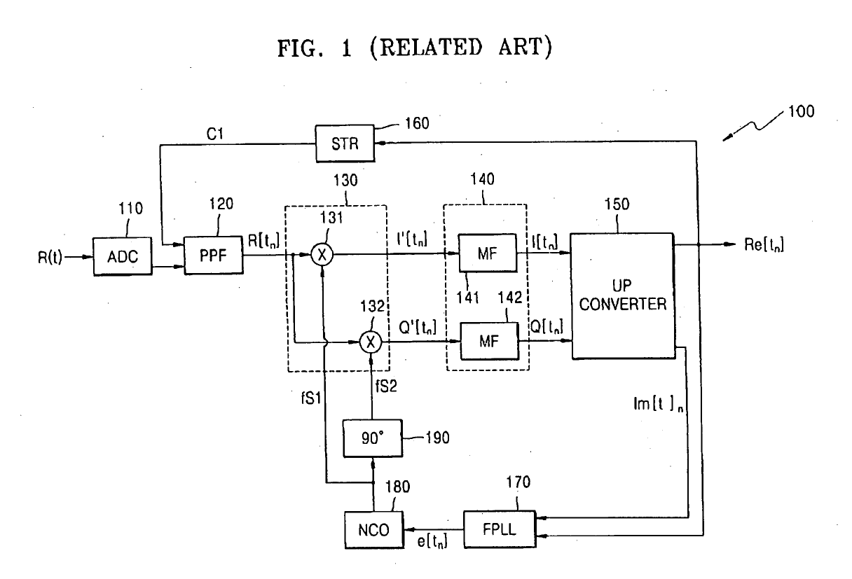

FIG. 2 is a block diagram of an ATSC DTV demodulator, according to an exemplary embodiment of the present invention;

FIG. 3 is a block diagram of a mean power frequency discriminator (MP-FD) 271 of FIG. 2, according to an exemplary embodiment of the present invention;

FIG. 4 is a example of a frequency spectrum of a third branch signal represented in Equation 4; and

FIG. 5 is an example of a function of an error signal e[tₙ], which may be output from the MP-FD 271 of FIG. 3 with respect to frequency offset Δω.

### DETAILED DESCRIPTION OF EXEMPLARY EMBODIMENTS OF THE PRESENT INVENTION

Exemplary embodiments of the present invention will now be described with reference to the accompanying drawings. The present invention may, however, be embodied in many different forms and should not be construed as being limited to the embodiments set forth herein; rather, these exemplary embodiments are provided so that this disclosure will be thorough and complete, and will fully convey the concept of the invention to those skilled in the art. Throughout the drawings, like reference numerals refer to like elements.

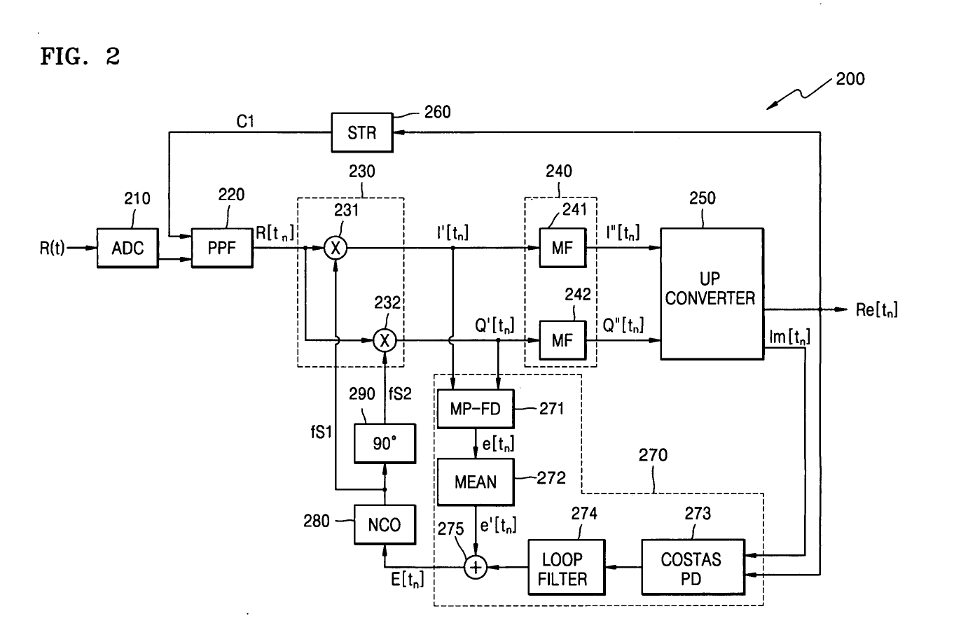

FIG. 2 is a block diagram of a DTV (for example, an ATSC DTV) demodulator, according to an exemplary embodiment of the present invention. A DTV (for example, an ATSC DTV) demodulator 200 may include an ADC 210, a PPF 220, multipliers 230, a low-pass filters (LPF) 240, an up converter 250, an STR 260, a frequency and phase tracking circuit 270, an NCO 280, and a phase shifter 290.

The ADC 210 may convert an analog signal R(t), which may be transmitted from a DTV (for example, an ATSC DTV) transmitter (not shown) into a digital signal.

The PPF 220 may receive the digital signal from the ADC 210 and may generate a signal R[tₙ9 . The signal R[tₙ] may be sampled at a sampling frequency, for example,

$${f}_{S} ( = \frac{1}{{T}_{S}} ) ,$$

where T_{S} may denote a sampling time, tₙ=n×T_{S}, and n may be an integer. The operation of the PPF 220 may be controlled by at least one control signal C1, which may be output from the STR 260 .

The multipliers 230 may further include at least multipliers 231 and 232 . The multiplier 231 may multiply the sampled signal R[tₙ] by a frequency sinusoidal signal fs1 and may output an in-phase signal (for example, a branch in-phase signal) I′[tₙ] with the sampled signal R[tₙ]. The multiplier 232 may multiply the sampled signal R[tₙ] by a frequency sinusoidal signal fs2 and may output a quadrature signal (for example, a branch quadrature signal) Q′[tₙ] with the sampled signal R[tₙ].

The LPF 240 may further include matched filters MFs 241 and 242 .

The MF 241 may pass a lower frequency signal of the signal I′[tₙ] and may output a signal (for example, a branch signal) I″[tₙ]. The MF 242 may pass a lower frequency signal of the signal Q′[tₙ] and may output a signal (for example, a branch signal) Q″[tₙ].

The up converter 250 may transmit a real number component signal Re[tₙ], which may be extracted from the sampled signal R[tₙ] using the signals I″[tₙ] and/or Q″[tₙ],to the STR 260 and the PFLL 270. The up converter 250 may transmit an imaginary number component signal Im[tₙ], which may be extracted from the sampled signal R[tₙ] using the signals I″[tₙ] and/or Q″[tₙ],to the PFLL 270 .

The STR 260 may utilize the real number component signal Re[tₙ] and may output at least the control signal C1, which may control the sampling frequency, for example,

$${f}_{S} ( = \frac{1}{{T}_{S}} ) ,$$

and/or the timing phase in the PPF 220 .

The frequency and phase tracking circuit 270 may include at least an MP-FD 271, a mean value calculator 272, a Costas phase discriminator (PD) 273, a loop-filter 274, and an adder 275.

The MP-FD 271 may perform an operation on the signals I′[tₙ] and Q′[tₙ], which may be output from the multipliers 230, and may output an error signal e[tₙ], which may correspond to a frequency offset Δω of the sampled signal R[tₙ].

The mean calculator 272 may calculate a mean of the error signal e[tₙ] received from the MP-FD 271 and may output another error signal e[tₙ]. The error signal e[tₙ] may include information concerning the frequency offset Δω of the sampled signal R[tₙ] and may control (for example, adaptively control) an oscillation frequency of the frequency sinusoidal signal fs1. The frequency sinusoidal signal fs1 may be output from the NCO 280 and may acquire a frequency of the carrier signal.

The Costas PD 273 may use the real and/or imaginary number component signals Re[tₙ] and/or Im[tₙ] and may output a signal, which may include information concerning a phase offset of the carrier signal. The loop-filter 274 may remove noise (for example, high frequency noise) from the signal, which may be output from the Costas PD 273.

The adder 275 may add the error signal e[tₙ] to a signal output from the loop-filter 274 and may output another error signal E[tₙ], which may include information concerning carrier frequency and/or phase offset of the sampled signal R[tₙ].

The carrier frequency may be obtained through a path including, for example, the MP-FD 271, the mean calculator 272, and the adder 275. A phase of the carrier frequency may be tracked through another path including, for example, the Costas PD 273, the loop-filter 274, and the adder 275.

The NCO 280 may output the frequency sinusoidal signal fs1, COS((ω_{C}+Δω)tₙ+φ)), the oscillation frequency of which may be determined by the error signal E[tₙ].

The phase shifter 290 may shift a phase of the frequency sinusoidal signal fs1, COS((ω_{C}+Δω)tₙ+φ)), by 90° and may output the frequency sinusoidal signal fs2, sin((ω_{C}+Δω)tₙ+φ))

Δω and φ may denote frequency offset and phase offset between the DTV (for example, an ATSC DTV) transmitter and the DTV (for example, an ATSC DTV) demodulator 200, which may be used in a DTV (for example, an ATSC DTV) receiver (not shown).

The sampled signal R[tₙ], which may be output from the PPF 220, may be represented as in Equation 1:
R[tₙ]=X_{VSB,Re}[tₙ]cos(ω_{C}·tₙ)−X_{VSB,Im}[tₙ]sin(ω_{c}·tₙ)+n[tₙ] (1)
wherein X_{VSB,Re}[tₙ] and X_{VSB,Im}[tₙ] may denote vestigial side band signals, which may be real and imaginary parts of the sampled signal R[tₙ]. X_{VSB,Re}[tₙ] and X_{VSB,Im}[tₙ] may be transmitted from the DTV (for example, an ATSC DTV) transmitter to the DTV (for example, an ATSC DTV) receiver and may be sampled at a sampling frequency of, for example,

$${f}_{S} ( = \frac{1}{{T}_{S}} ) .$$

ω_{C} may denote the carrier frequency which may be transmitted from the DTV (for example, an ATSC DTV) transmitter, n[tₙ] may denote noise (for example, Additive White Gaussian Noise (AWGN)), which may be sampled at a sampling frequency of, for example, f_{S}, where tₙ=n×T_{S},and n may be an integer.

The vestigial side band signals X_{VSB,Re}[tₙ] and X_{VSR,Im}[tₙ] may include pilot tones, which may be defined in accordance with DTV standards (for example, ATSC DTV standards). The noise (for example, AWGN) n[tₙ] in Equation 1 may not affect the mean characteristics of the error signal e′[tₙ] , which may be output from the frequency and phase tracking circuit 270.

As illustrated in FIG. 2, the sampled signal R[tₙ] may be multiplied by the frequency sinusoidal signal fs1, COS((ω_{C}+Δω)tₙ+φ)) , by the multiplier 231 and may generate the signal (for example, the branch signal) I′[tₙ].

The sampled signal R[tₙ] may be multiplied by the frequency sinusoidal signal fs2, sin((ω_{C}+Δω)tₙ+φ)) , which may be output from the phase shifter 290, by the multiplier 232 and may generate the signal (for example, the branch signal) Q′[tₙ].

The signals (for example, branch signals) I′[tₙ] and Q′[tₙ] may be represented by, for example, equations 2 and 3, respectively:

$$\begin{matrix}{I}^{′} [ {t}_{n} ] = \frac{1}{2} {x}_{VSB , Re} [ {t}_{n} ] \cdot [ cos ( Δω \cdot {t}_{n} + ϕ ) + cos ( ( 2 {ω}_{c} + Δω ) \cdot {t}_{n} + ϕ ) ] + \frac{1}{2} {x}_{VSB , Im} [ {t}_{n} ] \cdot [ sin ( Δω \cdot {t}_{n} + ϕ ) - sin ( ( 2 {ω}_{c} + Δω ) \cdot {t}_{n} + ϕ ) ] & ( 2 ) \\ {Q}^{′} [ {t}_{n} ] = \frac{1}{2} {x}_{VSB , Im} [ {t}_{n} ] \cdot [ cos ( Δω \cdot {t}_{n} + ϕ ) - cos ( ( 2 {ω}_{c} + Δω ) \cdot {t}_{n} + ϕ ) ] - \frac{1}{2} {x}_{VSB , Re} [ {t}_{n} ] \cdot [ sin ( Δω \cdot {t}_{n} + ϕ ) + sin ( ( 2 {ω}_{c} + Δω ) \cdot {t}_{n} + ϕ ) ] & ( 3 )\end{matrix}$$

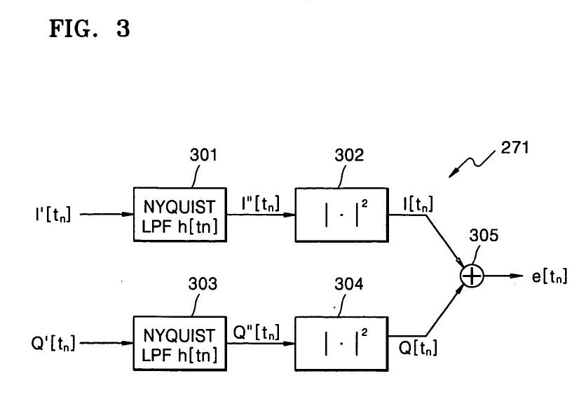

FIG. 3 is a block diagram of the MP-FD 271, according to an exemplary embodiment of the present invention. The MP-FD 271 may include at least Nyquist low-pass filters (LPFs) 301 and 303, square functions 302 and 304, and an adder 305.

The Nyquist LPF 301 may satisfy a Nyquist criterion and may filter the signal (for example, a branch signal) I′[tₙ]which may output the signal (for example, a branch signal) I″[tₙ].

The Nyquist LPF 303 may satisfy the Nyquist criterion and may filter the signal (for example, a branch signal) Q′[tₙ], which may output the signal (for example, a branch signal) Q″[tₙ].

The signal I″[tₙ] may be represented by, for example, equation 4:

$${I}^{′′} [ {t}_{n} ] = \frac{1}{2} {x}_{VSB , Re} [ {t}_{n} ] cos ( Δω {t}_{n} + ϕ ) * h [ {t}_{n} ] + \frac{1}{2} {x}_{VSB , Im} [ {t}_{n} ] sin ( Δω {t}_{n} + ϕ ) * h [ {t}_{n} ] \qquad ( 4 )$$

wherein h[·] may denote impulse responses of the Nyquist LPFs 301 and 303, and * may denote convolutions.

The vestigial side band signals X_{VSBR,Re [t}ₙ] and X_{VSB,Im [t}ₙ] may be represented by, for example, equations 5 and 6, respectively:
X_{VSB,Re}[tₙ]=[s[tₙ]cos(ωₗ·tₙ)]*MF_{Tx} (5)
X_{VSB,Im}[tₙ]=[s[tₙ]sin(ωₗ·tₙ)]*MF_{Tx} 6)
wherein s[tₙ] may denote transmitted data, ωₗmay denote an operation frequency of a down converter of the DTV (for example, an ATSC DTV) transmitter, and MF TX may denote data, which may be output from an MF of the DTV (for example, an ATSC DTV) transmitter and/or an in-phase (I) component of a transmitted signal in Equation 5 and a quadrature (Q) component of the transmitted signal in Equation 6.

The frequency and phase tracking circuit 270 and/or the DTV (for example, an ATSC DTV) demodulator 200 may reduce the time for tracking frequency and/or phase offset.

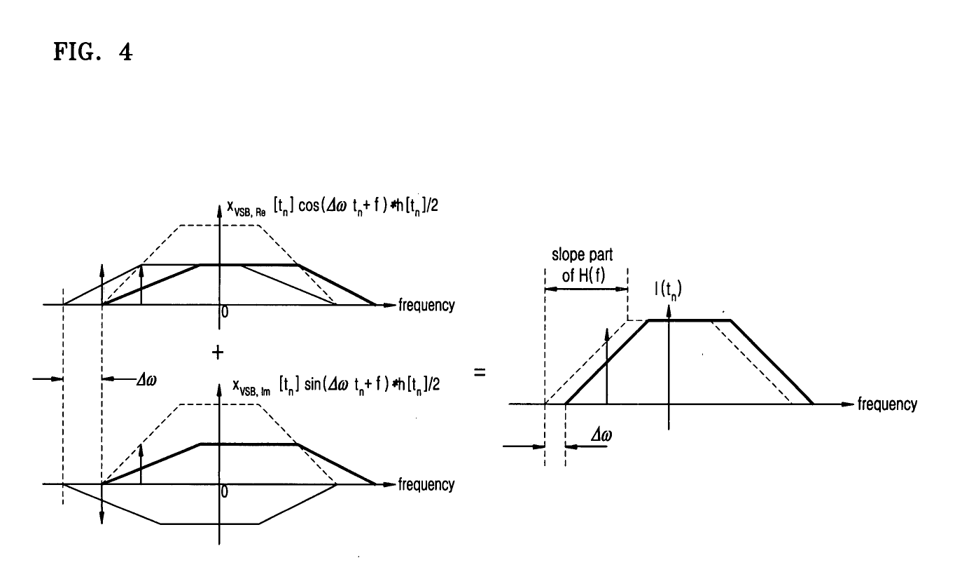

FIG. 4 is an example of a frequency spectrum of the signal I″[tₙ] represented by, for example, equation 4. Referring to FIG. 4, dotted lines may denote H(f), which may represent the Fourier Transform of the impulse responses h[·]. A Fourier Transformation may be performed on sin(ω₀^{t}) and/or cos(ω₀^{t}) and Equations 7 and/or 8 may be obtained, respectively:

$$\begin{matrix}\frac{j}{2} \{ δ ( f + {f}_{0} ) - δ ( f - {f}_{0} ) \} & ( 7 ) \\ \frac{1}{2} \{ δ ( f + {f}_{0} ) + δ ( f + {f}_{0} ) \} & ( 8 )\end{matrix}$$

wherein j=\sqrt{−1}.

A Fourier Transform H(f) may be performed on vestigial side band functions X_{VSB,Re}[tₙ]cos(Δωtₙ+φ) and/or X_{VSB,Im}[tₙ]sin(Δωtₙ+φ), and Equations 9 and/or 10 may be obtained, respectively:

$$\begin{matrix}\frac{1}{2} \{ {X}_{VSB , Re} ( f + Δ f ) - {X}_{VSB , Re} ( f - Δ f ) \} & ( 9 ) \\ \frac{j}{2} \{ {X}_{VSB , Im} ( f + Δ f ) - {X}_{VSB , Im} ( f - Δ f ) \} & ( 10 )\end{matrix}$$

In the example graph at the top of FIG. 4, a full line and a thick full line may denote the left and the right spectrum components, respectively, of the sampled signal R[tₙ]. In the example graph at the bottom of FIG. 4, a full line and a thick full line may denote the left and the right spectrum components, respectively, of the vestigial side band I″[tₙ]={R[tₙ]·cos(2π(f_{c}+Δf )tₙ+φ]}*h[tₙ]), which maybe output from the Nyquist LPF 301. A dotted line may denote the spectrum of h[tₙ].

In the example graph at the bottom of FIG. 4, a width of a carrier frequency offset Δω may be less, or substantially less, than a width of a slope of, for example, a portion of, H(f) and power measurements of the signal I[tₙ] may vary with the carrier frequency offset Δω.

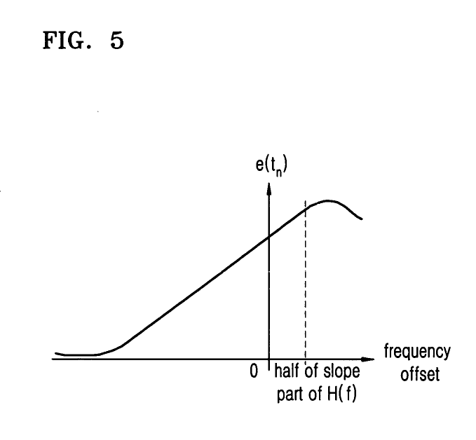

FIG. 5 is an example of a curve illustrating a function of the error signal e[tₙ], which may be output from the MP-FD 271. For exemplary purposes, the curve is illustrated with respect to the frequency offset Δω. Referring to FIG. 5, the example curve may be asymmetric on a y-axis direction basis.

Referring to FIG. 4, the carrier frequency offset Δω may increase, the error signal e[tₙ] may move away of the profile of Fourier Transform H(f), and the error signal e[tₙ] may be reduced.

That is, the carrier frequency offset Δω may be reduced, the spectrum of the error signal e[tₙ] may move closer to the profile of Fourier Transform H(f) and the error signal e[tₙ] may be increased.

With regard to FIG. 3, the error signal e[tₙ], which may correspond to the carrier frequency offset Δω, may be obtained by adding power measurements of the signals I′[tₙ] and Q′[tₙ]. Similar, or substantially similar, procedures may be applied to the Nyquist LPF 303 and/or the square function 304, which may constitute a path illustrated in FIG. 3.

A frequency phase locked loop circuit and/or a DTV (for example, an ATSC DTV) demodulator, according to exemplary embodiments of the present invention, may track a frequency and/or phase in a reduced amount of time when a pilot tone may fade, or substantially fade. The pilot tone may fade, or substantially fade, due to factors such as, for example, multipath channels.

Although exemplary embodiments of the present invention have been described with respect to factors such as multipath channels, it will be understood that many different factors may cause fading, or substantial fading, of a pilot tone.

Although exemplary embodiments of the present invention have been described with respect to a Fourier transform, it will be understood that any other suitable transform may be implemented, as desired by one of ordinary skill in the art.

Although exemplary embodiments of the present invention have been described with respect to the frequency domain, it will be understood that any other suitable domain (for example, the time domain) may be implemented, as desired by one of ordinary skill in the art.

Although exemplary embodiments of the present invention have been described with respect to DTV standards (for example, ATSC DTV standards), it will be understood that various aspects of exemplary embodiments of the present invention, for example pilot tones, may be in accordance with any suitable standard as desired by one of ordinary skill in the art.

Although exemplary embodiments of the present invention have been illustrated and described with respect to, for example, two Nyquist filters, two square functions, etc., it will be understood that any number of components (i.e. Nyquist filters, square functions, etc.) may be used as desired by one of ordinary skill in the art.

Although exemplary embodiments of the present invention have been described with respect to a Costas phase discriminator, it will be understood that any suitable phase discriminator may be utilized as desired by one of ordinary skill in the art.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A frequency phase locked loop circuit comprising:
a mean power frequency discriminator adapted to perform an operation on a first and a second signal to output a first error signal corresponding to a frequency offset of a sampled signal;
a mean calculator adapted to calculate a mean of the first error signal and output a second error signal including information concerning frequency offset of a carrier signal;
a phase discriminator adapted to use real and imaginary number component signals of the sampled signal to output a signal including information concerning phase offset of the carrier signal;
a loop-filter adapted to remove noise from the signal output from the phase discriminator; and
a first adder adapted to add the second error signal to a signal output from the loop-filter to output a third error signal comprising information concerning the carrier frequency and phase offset of the sampled signal, wherein the frequency phase locked loop circuit is adapted to obtain the carrier frequency through the mean power frequency discriminator, the mean calculator, and the first adder and track a phase of the carrier frequency through the phase discriminator, the loop filter, and the first adder.

2. The frequency phase locked loop circuit of claim 1, wherein the mean power frequency discriminator further comprises,
at least two Nyquist low-pass filters adapted to filter at least a first and a second branch signal according to a Nyquist criterion to output a third and a fourth branch signal;
at least two square functions adapted to perform square operations on the third and the fourth branch signal; and
an adder adapted to add the data output from the at least two square functions to output an error signal.

3. A digital television demodulator comprising:
an analog-to-digital converter adapted to convert an analog signal transmitted from a digital television transmitter into a digital signal;
a poly phase filter adapted to receive the digital signal from the analog-to-digital converter and a control signal from a symbol timing recoverer to generate a sampled signal that is sampled at a sampling frequency , which varies according to the control signal;
a multiplier adapted to receive the sampled signal and first and second frequency sinusoidal signals to output a first signal in phase with the sampled signal and a second signal out of phase with the sampled signal;
a low-pass filter adapted to filter the first and second signals to output third and fourth signals;
an up converter adapted to output real and imaginary number component signals, extracted from the sampled signal, using the third and fourth signals;
the symbol timing recoverer adapted to output the control signal using the real number component signal;
a frequency phase locked loop circuit adapted to output a fifth signal, including information concerning frequency offset and phase offset of the sampled signal, using the first and second signals and the real and imaginary number component signals;
a number controlled oscillator adapted to output the first frequency sinusoidal signal determined by the fifth signal output from the frequency phase locked loop circuit; and
a phase shifter adapted to shift a phase of the first frequency sinusoidal signal by an angle to output the second frequency sinusoidal signal.

4. The digital television demodulator of claim 3, wherein:
the sampled signal is represented as R[tₙ], wherein tₙ=n ×T_{S}, where
$${T}_{S} ( = \frac{1}{{f}_{S}} )$$
and denotes a sampling time, and n is an integer;
the first frequency sinusoidal signal is represented as cos((ω_{C}+Δω)tₙ+φ) , where Δω and φ denote the frequency offset and the phase offset between the digital television transmitter and the digital television demodulator used in a digital television receiver;
the angle is 90° ; and
the second frequency sinusoidal signal is represented as sin((ω_{c}+Δω)tₙ+φ) .

5. The digital television demodulator of claim 3, wherein the multiplier comprises:
at least two multipliers adapted to multiply the sampled signal by the first frequency sinusoidal signal to output the first signal in phase with the sampled signal and multiply the sampled signal by the second frequency sinusoidal signal to output the quadrature second signal 90° out of phase with the sampled signal.

6. The digital television demodulator of claim 3, wherein the low-pass filter comprises:
at least two filters adapted to filter the first signal to output the third signal and filter the second signal to output the fourth signal.

7. The digital television demodulator of claim 3, wherein the frequency phase locked loop circuit comprises:
a mean power frequency discriminator adapted to perform an operation on the first and second branch signals to output a first error signal corresponding to the frequency offset of the sampled signal;
a mean calculator adapted to calculate a mean of the first error signal to output a second error signal including information concerning the frequency offset of the sampled signal;
a phase discriminator adapted to output a signal including information concerning phase offset of the carrier signal using the real and imaginary number component signals;
a loop-filter adapted to remove noise from the signal output from the phase discriminator; and
a first adder adapted to add the second error signal output from the mean calculator to a signal output from the loop-filter to output the third error signal including information concerning carrier frequency and phase offset of the sampled signal,
wherein the frequency phase locked loop circuit obtains the carrier frequency through a first path including the mean power frequency discriminator, the mean calculator, and the first adder and tracks a phase of the carrier frequency through a second path including the phase discriminator, the loop filter, and the first adder.

8. The digital television demodulator of claim 7, wherein the mean power frequency discriminator comprises:
at least two Nyquist low-pass filters adapted to filter the first and second signals according to a Nyquist criterion to output a third signal and a fourth signal;
at least two square functions adapted to perform a square operation on the third signal and the fourth signal; and
a second adder adapted to add the data output from the at least two square functions to output the first error signal.

9. A frequency phase locked loop circuit adapted to receive at least a first branch signal in phase with a sampled signal, a second branch signal out of phase with the sampled signal, and real and imaginary number component signals of the sampled signal and output an error signal including information concerning a carrier frequency and phase offset of the sampled signal.

10. The frequency and phase locked loop circuit of claim 9, further including,
a mean power frequency discriminator adapted to perform an operation on a first and a second signals to output a first error signal corresponding to frequency offset of the sampled signal;
a mean calculator adapted to calculate a mean of the first error signal and output a second error signal including information concerning frequency offset of a carrier signal;
a phase discriminator adapted to use the real and imaginary number component signals to output a signal including information concerning phase offset of the carrier signal;
a loop-filter adapted to remove noise from the signal output from the phase discriminator; and
a first adder adapted to add the second error signal to a signal output from the loop-filter to output the error signal comprising information concerning the carrier frequency and phase offset of the sampled signal.

11. A mean power frequency discriminator comprising:
at least two Nyquist low-pass filters adapted to filter at least a first and a second branch signal according to a Nyquist criterion to output a third and a fourth branch signal;
at least two square functions adapted to perform square operations on the third and the fourth branch signal; and
an adder adapted to add the data output from the at least two square functions to output an error signal.

12. A method for obtaining a carrier frequency and tracking a phase of the carrier frequency comprising:
performing an operation on a first and a second signal to output a first error signal corresponding to a frequency offset of a sampled signal;
calculating a mean of the first error signal and output a second error signal including information concerning frequency offset of a carrier signal;
outputting a first output signal including information concerning phase offset of the carrier signal based on a real and imaginary number component signals;
producing a second output signal by removing noise from the first output signal;
producing a third output signal based on the second error signal and the second output signal and including information concerning the carrier frequency and phase offset of the sampled signal; and
obtaining the carrier frequency and tracking the phase of the carrier frequency based on the information in the third output signal.

13. A method for producing an error signal including information concerning a frequency carrier offset of a carrier signal, the method comprising:
filtering at least a first and a second branch signal according to a Nyquist criterion to output a third and a fourth branch signal;
performing square operations on the third and the fourth branch signal; and
adding the third and fourth branch signals to output an error signal including information concerning the frequency carrier offset of a carrier signal.

14. A frequency phase locked loop circuit for implementing the method of claim 12.

15. A digital television demodulator for implementing the method of claim 12.

16. A frequency phase locked loop circuit for implementing the method of claim 13.

17. A digital television demodulator for implementing the method of claim 13.

18. A mean power frequency discriminator for implementing the method of claim 13.
